(19) United States
(12) Patent Application Publication
(10) Pub. No.: US 2020/0006913 A1
(43) Pub. Date: Jan. 2, 2020

(54) Optoelectronic Component and Method for Producing an Optoelectronic Component

(71) Applicant: OSRAM GmbH, München (DE)

(72) Inventors: Angela Eberhardt, Augsburg (DE); Florian Peskoller, Ingolstadt (DE); Jörg Frischeisen, Schwabmünchen (DE); Thomas Huckenbeck, Augsburg (DE); Michael Schmidberger, Schwabmünchen (DE); Jürgen Bauer, Wielenbach (DE)

(21) Appl. No.: 16/488,529

(22) PCT Filed: Feb. 20, 2018
(86) PCT No.: PCT/EP2018/054186

§ 371 Date: Aug. 23, 2019

(30) Foreign Application Priority Data
Feb. 28, 2017 (DE) 102017104134.6

(51) Int. Cl. H01S 5/00; C03C 4/12; C03C 14/00; C09K 11/02; C09K 11/77; C03C 17/00

(52) U.S. Cl. CPC H01S 5/005; C03C 4/12; C03C 14/004; F21S 41/16; C09K 11/7706; C03C 17/008; C09K 11/02

(57) ABSTRACT

An optoelectronic component and a method for producing an optoelectronic component are disclosed. In an embodiment an optoelectronic component includes at least one laser source configured to emit at least one laser beam during operation and a self-supporting conversion element arranged in a beam path of the laser beam, wherein the self-supporting conversion element comprises a substrate followed by a first layer, the first layer being directly bonded to the substrate and comprising at least one conversion material embedded in a glass matrix, wherein the glass matrix has a proportion of 50 vol % to 80 vol % inclusive in the first layer, wherein the substrate is free of the glass matrix and of the conversion material and mechanically stabilize the first layer, and wherein the first layer has a layer thickness of less than 200 μm.

This patent application is a national phase filing under section 371 of PCT/EP2018/054186, filed Feb. 20, 2018, which claims the priority of German patent application 102017104134.6, filed Feb. 28, 2017, each of which is incorporated herein by reference in its entirety.

### TECHNICAL FIELD

The invention concerns an optoelectronic component. Furthermore, the invention concerns a method for manufacturing an optoelectronic component.

### BACKGROUND

In so-called LARP applications (Laser Activated Remote Phosphor) it is necessary to generate a high luminance. In addition, a small spot widening is important, i.e., the extent to which the light area (e.g., related to 1/e² value of the maximum) of the converted radiation increases compared to the light area (=excitation area) of the excitation laser beam, the contrast between areas to be illuminated and areas not to be illuminated (e.g., for adaptive headlights), color homogeneity over the converter surface and over the beam angle, the efficiency and/or stability (e.g., with regard to humidity, radiation, temperature, chemical influences, etc. in order to guarantee a long service life of the component). The term LARP applications is used here and in the following to refer to applications that use a laser source with at least one laser beam to make a conversion element usable as a light source. This does not exclude the possibility that a part of the laser light is still present and can therefore be included in the light source.

### SUMMARY OF THE INVENTION

Embodiments provide an optoelectronic component that is suitable for LARP applications, is stable for LARP applications or has a high luminance. Further embodiments provide a method for manufacturing an optoelectronic component that produces a stable optoelectronic component.

In at least one embodiment, the optoelectronic component has at least one laser source which emits at least one laser beam during operation. Furthermore, the component has a self-supporting conversion element arranged in the beam path of the laser beam. The self-supporting conversion element comprises a substrate followed by a first layer. The first layer is directly bonded to the substrate. The first layer comprises at least one conversion material embedded in a glass matrix. The glass matrix has a proportion between 50 vol % and 80 vol % (calculated without pores) in the first layer. The substrate is free of the glass matrix and the conversion material and serves to mechanically stabilize the first layer. The first layer has a thickness of less than 200 μM.

The component can optionally be mounted mechanically immovable with respect to the laser source or light source. Mechanically immovable means here in particular that the relative spatial position of the conversion element and the laser source does not change. The laser source, preferably including primary beam-guiding optics, can have at least one laser beam that can vary its beam direction. The variation of the beam direction can be realized by different technologies. This includes, e.g., MEMS (micro-electro-mechanical system) elements or piezo drives, but also polygon mirrors or rotating rollers, but also typical technologies used in CD and Blue Ray players such as “Voice Coil Actuators” can be used here. In general, all technologies can be used that allow a laser beam to be scanned together with primary optical elements via the conversion element. The conversion element can be used in transmissive or reflective configuration. The described conversion element can be used in combination with such technologies in a system especially advantageously in scanning LARP systems, especially in the AM area (AM=Automotive). A detailed description of these systems is given below. Deflection is preferably or exclusively provided by the movement of one or more optical elements such as mirrors and/or lenses.

Direct means here that no further layers or elements are arranged between the first layer and the substrate. In other words, the first layer can be attached to the substrate without the use of adhesives. The first layer is therefore not bonded to the substrate with an additional adhesive material. The substrate may have other layers, such as the coating of the substrate. The coating can be dichroic. Additionally or alternatively, the substrate can have an anti-reflective coating.

The inventors have recognized that the use of the component described herein in a LARP assembly has improved heat dissipation, radiation stability and temperature stability compared to a conventional conversion element comprising organic matrix materials such as silicones or epoxies.

Very thin layers with a high proportion of conversion material in the glass matrix can be produced. The conversion element can exhibit high light scattering and is preferably made exclusively of inorganic materials. Preferably the conversion material and the glass matrix are arranged on a transmissive substrate.

The substrate allows the glass matrix to be processed at a lower viscosity during the production of the conversion element and can therefore be thinner and filled higher with the conversion material than a conversion element formed without substrate. The substrate and matrix material have good moisture stability. In the case of a glass, the substrate preferably has a higher softening temperature and/or a higher melting temperature than the glass matrix and thus has a shaping effect.

In the case of a conversion element without substrate, the shape would be lost due to the surface tension if the glass matrix becomes too low viscous.

In addition, the scattering through pores and refractive index differences is more variable or adjustable than with other inorganic matrix materials. The glass matrix shows a certain residual porosity, i.e., it is poor in pores but never completely free of pores. The surface of the glass matrix can be largely closed and relatively smooth.

Previously known conversion elements for LARP applications show the disadvantage of spot widening and/or low contrast. However, these parameters are very important, for example, for automotive applications, such as the use of conversion elements in a headlamp, especially for applications targeting an ADB (Advanced Driving Beam) system, also known as “Glare-Free HB”. These systems can be realized with one of the above mentioned beam deflection technologies. One or more laser beams are scanned here over a conversion element. This can be realized in one or two dimensions. The resulting local converted light distribution is imaged with a secondary optic into the far field. By synchronizing the laser driver and beam deflection elements, a targeted control of the light distribution can be achieved, including switching off and/or dimming the laser and thus also the resulting light distribution in certain areas. This can be used to hide other road users (oncoming and preceding vehicles, etc.). As soon as these have disappeared from the field of vision of the headlights, the de-glaring zone can be fully illuminated again. Especially to achieve good performance in vertical and horizontal de-glaring zones, it is essential to optimize the topics spot widening and contrast. Legal regulations can be found in the well-known ECE-R 123 standard, for example, the use of conversion elements in a headlamp.

But also other light distributions, such as dimmed lights or fog light, require sufficient sharpness and contrast in the vertical direction to meet the legal requirements of ECE-R 19 and ECE-R 112. Alternatively, the excitation can be static. In this case, the excitation area of the laser beam on the conversion element remains spatially constant. The mixture of converted light and any remaining excitation light can meet other optical elements, for example, for beam shaping or focusing. In addition, the mixture can encounter optical components such as MEMS or polygon mirrors in order to achieve spatial and/or temporal modulation of the radiation on the surface to be illuminated, e.g., for an ADB system.

According to at least one embodiment, the component has at least one wavelength-converting conversion material. The conversion material absorbs radiation with a first dominant wavelength (and possibly a surrounding spectral range), in particular from the laser source, and at least partially converts it into radiation with a second dominant wavelength (and possibly a surrounding spectral range), preferably greater than the first dominant wavelength. The dominant wavelength is known to the expert and is therefore not explained here. Inorganic materials with wavelength converting properties can preferably be used as conversion materials. For example, garnet, orthosilicate and/or nitride silicate are suitable as conversion materials.

Other materials for the conversion material are, for example:

(Y,Gd,Tb,Lu)₃(Al,Ga)₅O₁₂:Ce³⁺,

(Sr,Ba,Ca,Mg)₂Si₅N₈:Eu²⁺,

(Ca,Sr)₈Mg(SiO₄)₄Cl₂:Eu²⁺,

(Sr,Ba,Ln)₂Si(O,N)₄:Eu²⁺ with Ln: at least one element of the lanthanides,

(Sr,Ba)Si₂N₂O₂:Eu²⁺

(Ca,Sr,Ba)₂SiO₄:Eu²⁺,

(Sr,Ca)AlSiN₃:Eu²⁺,

(Sr,Ca)S:Eu²⁺,

(Sr,Ba,Ca)₂(Si,Al)₅(N,O)₈:Eu²⁺,

(Sr,Ba,Ca)₃SiO₅:Eu²⁺,

α-SiAlON:Eu²⁺,

β-SiAlON:Eu²⁺,

Ca(5−δ)Al(4−2δ)Si(8+2δ)N₁₈O:Eu²⁺,

and other phosphors, luminescent materials, quantum dots, organic dyes or luminescent glass.

According to at least one embodiment, the conversion element has exactly one conversion material. Alternatively, more than one conversion material, for example, at least two conversion materials, can exist in the conversion element.

According to at least one embodiment, at least two different conversion materials are embedded in the glass matrix.

The conversion material may be capable of completely absorbing the radiation of the laser source, in particular one or more laser beams, and emitting it with a changed longer wavelength. In other words, a so-called full conversion takes place, i.e., the radiation from the laser source does not contribute at all or contributes less than 5% of the resulting total radiation.

Alternatively, the conversion material is capable of partially absorbing the radiation from the laser source so that the total radiation exiting the conversion element is composed of the laser radiation and the converted radiation. This can also be referred to as partial conversion. The total radiation can be white mixed light.

According to at least one embodiment, the conversion element has a first layer. The first layer may have a surface facing away from the substrate. The first layer can be structured. For example, the first layer can be polished, ground, etched and/or coated. The surface of the first layer is preferably rough. This allows the light extraction to be improved due to the scattering and thus also the contrast to be increased. A smooth surface can be helpful, for example, for subsequent coatings. For example, a smooth surface may also provide sufficiently good light extraction if the refractive index difference between the glass matrix and the phosphor is greater than or equal to 0.1 or greater than or equal to 0.15 or greater than or equal to 0.2 or greater than or equal to 0.25 or greater than or equal to 0.3 or greater than or equal to 0.35 or greater than or equal to 0.4 or greater than or equal to 0.5 or greater than or equal to 0.55 or greater than or equal to 0.6, so that light can be scattered on the phosphors. Better light extraction by increasing the refractive index difference can also be achieved by adding scattering particles to the glass matrix. In this case the difference in refractive index is between the glass matrix and the scattering particles. Ideally, the refractive index difference between the glass matrix and air should be as small as possible, i.e., less than or equal to 1.0 or less than or equal to 0.9 or less than or equal to 0.8 or less than or equal to 0.7 or less than or equal to 0.6 or less than or equal to 0.55 or less than or equal to 0.5. A better coupling against air can also be achieved or at least positively supported, for example, by an anti-reflective layer applied to the first layer and/or by a scattering layer.

According to at least one embodiment, the first layer has a layer thickness of less than 200 μM. In particular, the first layer shall have a layer thickness of at most 150 μm for partial conversion or a layer thickness of at most 140 μm or at most 130 μm or at most 120 μm or at most 110 μm or better at most 100 μm or preferably at most 90 μm or at most 80 μm or at most 70 μm or at most 60 μm at most 50 μm or at most 45 μm or at most 35 μm or at most 30 μm or at most 25 μm or at most 20 μm. Alternatively, the first layer has a layer thickness of at most 200 μm for full conversion or a layer thickness of at most 250 μm or at most 220 μm, better at most 200 μm, preferably at most 180 μm or at most 170 μm or at most 160 μm or at most 150 μm or at most 100 μm or at most 90 μm or at most 80 μm or at most 70 μm or at most 60 μm or at most 50 μm, ideally from 70 μm to 180 μm.

According to at least one embodiment, the conversion element has a substrate. The substrate can be transmissive or transparent. Here and in the following a substrate is referred to as transparent if it has an internal transmission of >90%, preferably >95%, particularly preferably >99%. Internal transmission here means the transmission without reflection at the surfaces (Fresnel reflection).

Alternatively, the substrate can also be reflective, preferably with a reflectance between 0.95 and 1. Materials selected from the following group can be used as substrate: Sapphire, ceramics, glass, glass-like materials, glass ceramics, and other transparent or translucent materials. Alternatively, the substrate may comprise a material or a combination of the following materials: aluminum oxide, polycrystalline aluminum oxide, ceramics, aluminum, copper, metals, highly reflective aluminum with/by applied layer system, e.g., of silver. The reflective formed substrates are suitable for the so-called reflective LARP and the transparent substrates for the transmissive LARP.

According to at least one embodiment, the conversion element has a substrate. The substrate can be glass, glass ceramic, sapphire, metal or ceramic. Preferably the substrate is glass or sapphire. For example, borosilicate glass such as D263, D263T or D263TECO from Schott or aluminosilicate glass such as AS87 eco from Schott can be used as glass. Alternatively, glass-like materials, polycrystalline aluminum oxide or other transparent or translucent materials can also be used. Preferably the substrate should have good stability against humidity, radiation and/or high temperatures.

According to at least one embodiment, the substrate has a high thermal conductivity of >0.2 W/(m*K), preferably ≥0.5 W/(m*K), particularly preferably ≥0.7 W/(m*K) or ≥1.0 W/(m*K) or ≥4.0 W/(m*K) or ≥10 W/(m*K). Glass has the lowest thermal conductivity. In addition, the substrate can exhibit good resistance to moisture, radiation and/or temperatures, which is particularly advantageous for automotive applications. For example, the substrate shows no noticeable change in transmissive and reflective properties after, e.g., a humidity test at 85° C. and 85% relative humidity at >=1000 h. In particular, no noticeable change means no measurable change or a maximum 5% deterioration in the primary and/or secondary wavelength range. The same applies for the long-term temperature resistance at ≥180° C., better ≥200° C. for ≥1 h, better ≥5 h, ideally ≥10 h, as well as for the radiation resistance. Diamond has a thermal conductivity of about 2300 W/(m*K), sapphire of about 40 W/(m*K). Both are very suitable as transparent materials. Glass has a thermal conductivity of approximately 0.75 W/(m*K) depending on the material.

According to at least one embodiment, the thickness of the substrate is between 50 μm to 700 μm, preferably between 100 μm to 500 μm.

The substrate can be structured. For example, the substrate may be a structured sapphire substrate or formed as one or more microlenses structured on the surface. The substrate may have a photonic crystal lattice on the surface. This is an advantage, especially in order to increase light injection and/or extraction and thus increase efficiency. On the other hand, an improved angle emission characteristic or a beam formation in one or different directions can be generated. The surface of the substrate can be modified by roughening, sandblasting, grinding, polishing or etching.

The substrate may have a coating. The coating can, for example, have a scattering layer to increase light extraction.

According to at least one embodiment, the substrate has a decoupling foil. This allows the input and output of radiation to be increased and thus the efficiency of the optoelectronic component to be increased. On the other hand, the decoupling foil can serve to shape or deflect the beam of radiation emitted by the laser source and direct the beam in a certain direction. In addition or alternatively, the substrate can have a thin coating, for example, of the glass matrix, which is applied after polishing.

According to at least one embodiment, the substrate has a coating. The coating can, for example, have a scattering layer to increase light extraction. The coating can also be an encapsulation. The encapsulation is intended to protect against environmental influences such as moisture.

According to at least one embodiment, the substrate has functional coatings such as dichroic coatings, interference coatings or anti-reflective coatings. These coatings may have anti-reflective properties or filter properties. In addition, the substrate may have a dielectric back reflector on the surface which is opposite the main radiation exit surface and reflects back part of the radiation passing through the substrate to achieve more homogeneous edge emission and/or higher efficiency. The substrate may have dielectric filters that reflect at least part of the radiation and thus achieve full conversion, especially when excitation is by laser beam from the side of the first layer. For the so-called transmissive LARP applications, dichroic coatings are preferably used, which transmit most of the light emitted by the laser source and reflect most of the light emitted by the conversion material. It is advantageous if the dichroic coating or the layer stack is arranged between the substrate and the glass matrix and the excitation takes place by means of a laser beam from the substrate side. This allows higher efficiency to be achieved as the transmission of the excitation laser beam can be increased and the converted light emitted or scattered in the direction of the substrate is largely reflected back in the forward direction. In the case of a reflective application, the primary and secondary radiation is ideally well reflected. In the case of a reflective application, a dichroic coating or a stack of layers is not absolutely necessary, as long as the substrate is already reflective and ideally reflects the primary and secondary radiation well. Alternatively, a reflective layer may be present between the substrate and the first layer, which alone or in combination with the substrate ideally reflects the primary and secondary radiation well. Such a reflective layer can be, for example, a silver layering or an inorganic reflective coating. Optionally, the substrate can have a dichroic coating or a stack of layers as well as a reflective layer. This option is also possible with a substrate that is already well reflective, as it can increase efficiency, for example.

The changes to the substrate described here can be made individually or in combination, so that both the substrate side facing the main radiation exit surface and the opposite substrate side can be changed simultaneously or individually.

The dichroic coating can be applied on the substrate side facing the first layer. In general, a dichroic coating consists of several thin layers with refractive index differences to use interference for the wavelength and directional variation of radiation in the system. Here the dichroic coating can have two main functions: On the one hand, it ensures a high transmission of the incoming radiation and, on the other hand, a high reflectivity of the converted light coming from the conversion element. Both effects increase efficiency or effectiveness. This mode of operation is known to the expert and is therefore not explained in detail here.

The dichroic coating described above can alternatively or additionally be arranged on any other outer surface of the substrate and/or on its edge sides.

According to at least one embodiment, the component has a substrate on which the glass matrix is arranged, wherein the laser beam strikes the conversion material and at least partially converts the laser radiation into radiation with a changed longer wavelength, and wherein the primary and secondary radiation are reflected on the substrate or in combination with a reflective layer and/or a dichroic layer stack located between the substrate and the glass matrix, and wherein the reflected radiation emerges again via the conversion material.

According to at least one embodiment, the substrate has a filter that can selectively absorb wavelengths. For example, the substrate material can be a filter glass, such as a short pass, long pass or bandpass filter. This can be especially advantageous in full conversion when the substrate absorbs the light emitted by the laser source, so that all the light emitted by the laser source can be converted, especially when the excitation is from the side of the first layer.

According to at least one embodiment, a dichroic coating, anti-reflective coating, encapsulation, decoupling film and/or other coatings may be applied additionally or alternatively on one or both sides of the first layer and/or on the edges of the first layer.

According to at least one embodiment, the conversion material and/or the glass matrix is produced on the substrate by doctoring, screen printing, stencil printing, dispensing, spray coating, spin coating, electrophoretic deposition or by a combination of these different methods.

The conversion element is self-supporting. The term self-supporting is used here and in the following to describe that the conversion element is supports itself and that no further elements are required for support. The conversion element can be processed in the so-called pick-and-place process without further support.

According to at least one embodiment, the conversion element has scattering particles or fillers. The scattering particles or fillers may be, for example, aluminum oxide, aluminum nitride, barium sulphate, boron nitride, magnesium oxide, titanium dioxide, silicon dioxide, silicon nitride, YAG, orthosilicate, zinc oxide or zirconium dioxide as well as AION, SiAlON or combinations or derivatives thereof or other ceramic or vitreous particles, metal oxides or other inorganic particles. The scattering particles or fillers can have different shapes, for example, spherical, rod-shaped or disc-shaped, with particle sizes ranging from a few nanometers to a few tens of micrometers. Smaller particles can be used to adjust the viscosity of the suspension. Larger particles can contribute to the production of a compact conversion element and/or to improved heat dissipation, moisture resistance, or thickness homogeneity. The scattering can be changed and/or the mechanical stability can be improved.

According to at least one embodiment, the conversion element is manufactured from several layers, which can vary in layer thickness, compactness, glass matrix, conversion material, scatters and/or fillers.

According to at least one embodiment, the conversion element has a glass matrix. The conversion material is introduced into the glass matrix, preferably dispersed. The conversion material can be homogeneously distributed in the glass matrix. Alternatively, the conversion material in the glass matrix may have a concentration gradient, for example, an increase in the concentration of the conversion material in the glass matrix in the direction away from the laser source. For example, larger particles can be arranged closer to the substrate and smaller particles can be arranged on the surface of the conversion element, i.e., on the side facing away from the substrate. This reduces backscattering. In particular, the backscattering of the blue light, i.e., the light emitted by the laser beam, can be reduced.

According to at least one embodiment, the conversion material and/or the glass matrix is inorganic. The conversion material does preferably not contain any organic dyes as conversion material.

According to at least one embodiment, the glass matrix is free of organic materials. Preferably the glass matrix is free of silicone and/or epoxy. This is an advantage as silicones and epoxies can degenerate under the influence of blue light. They do this particularly under the influence of high temperatures and high radiation densities of blue or short-wave light, as is often the case with LARP applications. Therefore, if the matrix contains silicone and/or epoxy, it can degenerate irreversibly. With scanning LARP, this is particularly critical if the light-deflecting element fails, increasing the average blue power density in the part of the conversion element in which the spot stops a lot.

According to at least one embodiment, the conversion element has surfaces that are smoothed or planarized. This can be done, for example, by grinding or polishing. This can be advantageous for applying coatings.

According to at least one embodiment, the conversion material is formed as particles. The mean diameter (d₅₀ value) can be between 0.5 μm and 50 μm, preferably between 2 μm and 40 μm, especially between 3 μm and 25 μm. In addition, there may be different conversion materials with different emission spectra. The polishing and/or structuring step can grind the particles of the conversion material and thus damage them. Therefore, after this structuring and/or polishing, a protective layer or encapsulation can be applied to increase the stability of the conversion materials.

The conversion element may have a certain porosity. A material, e.g., a polymer such as silicone or polysilazane or polysiloxane or ormocer or parylene or generally a material with low light absorption in the wavelength range of the excitation wavelength or the converted light, can be introduced into the pores.

In addition, a coating can be applied to the conversion element to close the pores of the conversion element. The coating may have the same material as the glass matrix of the first layer. The coating may also contain a filler. In addition or alternatively, the edges of the conversion element can be coated, for example, using molding or casting. Silicone with titanium dioxide particles, for example, can be attached to the edges of the conversion element for this purpose.

Between the substrate and the first layer there may be other layers, such as protective layers, that can protect the substrate from a hard conversion material. A protective layer can be made of aluminum oxide or silicon dioxide, for example.

The lateral expansion of the conversion element can be, for example, 10 mm×25 mm or a diameter of 2 mm. In principle, however, other dimensions are also possible.

According to at least one embodiment, the first layer has a glass matrix. The glass matrix preferably contains 80 to 50 vol % in the first layer (without any pores). The glass matrix has good moisture stability.

According to at least one embodiment, the proportion of the glass matrix in the first layer is greater than 0 vol % and less than 100 vol %, preferably between 50 vol % and 80 vol % (limits included), or 40 or 45 vol %, 50 or 51 vol %, 52 or 53 vol %, 54 or 55 vol %, 56 or 57 vol %, 58 or 59 vol %, 60 or 61 vol %, 62 or 63 vol %, 64 or 65 vol %, 66 or 67 vol %, 68 or 70 vol %, 71 or 72 vol %, 73 or 74 vol %, 75 or 76 vol %, 77 or 78 vol %, 79 or 80 vol %, 81 or 82 vol %, 83 or 84 vol %, 85 or 86 vol %, 90 or 95 vol %. The proportion of conversion material in the first layer can be between 0% and 100 vol %, preferably between 20 and 50 vol %, for example, 20, 22, 25, 28, 30, 32, 35, 38, 40, 45, 48 or 50 vol %.

According to at least one embodiment, the first layer has a thickness of <200 μm. Preferably the layer thickness is ≤150 μm or ≤100 μm. In addition to the degree of conversion, it should also be noted for the upper layer thickness limit that the conversion element still has sufficient heat dissipation, which tends to decrease with increasing layer thickness. The lower layer thickness limit is rather oriented towards the desired degree of conversion for which a certain amount of conversion material is required, since the substrate should already provide sufficient mechanical stability of the conversion element during handling.

According to at least one embodiment, the substrate has a higher softening temperature than the softening temperature of the glass matrix. This means that the first layer applied as a paste or dispersion can be baked and/or sintered and/or glazed without the substrate being thermally deformed.

According to at least one embodiment, the component has a dichroic layer stack arranged between the substrate and the glass matrix, wherein the laser beam transmits the glass matrix and the dichroic layer stack and the conversion material embedded in the glass matrix at least partially converts the transmitted radiation into radiation with changed longer wavelength, wherein the converted radiation is reflected by the dichroic layer stack at least partially, in particular by more than 80%.

According to at least one embodiment, the substrate is arranged between the laser source and the first layer. In reflective applications, the first layer is preferably located between the laser source and the substrate.

According to at least one embodiment, the substrate is arranged between the laser source and the first layer, especially for transmissive arrangements. Alternatively, the first layer is arranged between the laser source and the substrate, especially for reflective arrangements.

According to at least one embodiment, the first layer has a surface facing away from the substrate, which is structured or surface-treated. This means in particular that the surface is smoothed. For example, smoothing can be done by polishing, grinding, etching or general structuring or coating.

According to at least one embodiment, the glass matrix is oxidic and comprises or consists of at least one of the following materials or combinations: lead oxide, bismuth oxide, boron oxide, silicon dioxide, tellurium dioxide, zinc oxide, phosphorus pentoxide, aluminum oxide. The materials described here can be present individually or in combination in the glass matrix. The glass matrix preferably contains zinc oxide. Preferably the glass matrix is free of lead oxide.

According to at least one embodiment, the glass matrix comprises or consists of zinc oxide (ZnO), boron oxide (B₂O₃) and silicon dioxide (SiO₂).

According to at least one embodiment, the glass matrix comprises zinc oxide, at least one glass former and a network converter or an intermediate oxide. The glass former can be boric acid, silicon dioxide, phosphorus pentoxide, germanium dioxide, bismuth oxide, lead oxide and/or telluride oxide. The network converter or the intermediate oxide may be selected from the following group or combinations thereof: alkaline earth oxide, alkali oxide, aluminum oxide, zirconium oxide, niobium oxide, tantalum oxide, tellurium dioxide, tungsten oxide, molybdenum oxide, antimony oxide, silver oxide, tin oxide, rare earth oxides.

According to at least one embodiment, the glass matrix is a tellurite glass.

According to at least one embodiment, the glass matrix has a proportion of at least 60 vol % in the first layer.

According to at least one embodiment, the conversion element is inorganic. In other words, the conversion element has only inorganic components and is free of organic materials. For example, the conversion element has no silicone.

Glass can be used as a glass matrix. Oxidic glasses are preferred. Oxidic glasses can be, for example, but not limited to, silicate glasses, borate glasses, borosilicate glasses, aluminosilicate glasses, phosphate glasses, tellurite glasses or germanate glasses. In addition, optical glasses or glasses that have a low transformation temperature, so-called “low Tg” glasses, can also be used.

For example, glasses containing lead oxide can be used as glasses, such as mixtures of lead oxide and boron oxide (PbO—B2O3) or lead oxide and silicon dioxide (PbO—SiO2) or lead oxide, boron oxide and silicon dioxide (PbO—B2O3-SiO2) or lead oxide, boron oxide, zinc oxide (PbO—B2O3-ZnO) or lead oxide, boron oxide and aluminum oxide (PbO—B2O3-Al2O3).

The lead oxide containing glasses described here may also contain bismuth oxide or zinc oxide. These glasses may also contain, for example, alkaline earth oxides, alkali oxides, aluminum oxide, zirconium oxide, titanium dioxide, hafnium dioxide, niobium oxide, tantalum oxide, tellurium dioxide, tungsten oxide, molybdenum oxide, antimony oxide, silver oxide, tin oxide and/or other rare earth oxides.

According to at least one embodiment, the glass matrix is free of lead or lead oxide. For example, glasses containing bismuth oxide can be used. For example, glasses can be used that contain bismuth oxide and boron oxide (Bi2O3-B2O3) or bismuth oxide, boron oxide, silicon dioxide (Bi2O3-B2O3-SiO2) or bismuth oxide, boron oxide, zinc oxide (Bi2O3-B2O3-ZnO) or bismuth oxide, boron oxide, zinc oxide and silicon oxide (Bi2O3-B2O3-ZnO—SiO2). Glasses containing bismuth oxide may also contain other glass components such as alkaline earth oxides, alkali oxides, aluminum oxide, zirconium oxide, titanium dioxide, hafnium oxide, niobium oxide, tantalum oxide, tellurium oxide, tungsten oxide, molybdenum oxide, antimony oxide, silver oxide, tin oxide and/or other rare earth oxides.

Alternatively, lead oxide free glasses such as glasses containing zinc oxide can also be used. For example, zinc oxide and boron oxide (ZnO—B2O3) or zinc oxide, boron oxide and silicon dioxide (ZnO—B2O3-SiO2) or zinc oxide and phosphorus oxide (phosphorus pentoxide, ZnO—P2O5) or zinc oxide, tin oxide and phosphorus pentoxide (ZnO—SnO—P2O5) or zinc oxide and tellurium dioxide (ZnO—TeO2) can be used as a glass matrix.

The glasses containing zinc oxide may contain other components such as alkaline earth oxides, alkali oxides, aluminum oxide, zirconium oxide, titanium oxide, hafnium oxide, niobium oxide, tantalum oxide, tellurium dioxide, tungsten oxide, molybdenum oxide, antimony oxide, silver oxide, tin oxides and/or other rare earth oxides.

According to at least one embodiment, the glass matrix is a tellurite glass, a silicate glass, an aluminosilicate glass, a borate glass, a borosilicate glass or a phosphate glass.

According to at least one embodiment, the glass matrix has a softening temperature, which preferably lies in the range of 150-1000° C., better 150-950° C., in particular between 200-800° C., ideally in the range of 300-700° C. or in the range of 350-650° C. At the softening temperature, the glass has a viscosity of 10^{7.6} dPa*s as defined in ISO 7884. In addition, the glass matrix has a viscosity of 10⁵ dPa*s in the range of 150° C. and 900° C. or 1400° C., especially in the range of 250-1200° C., for example, in the range of 250-650° C. or in the range of 600-1200° C.

In particular, the upper temperature limit for the manufacture of the conversion element shall not exceed 1400° C. or 950° C., or ≤1350° C., or ≤1300° C., or ≤1250° C., or ≤1200° C., or ≤1150° C., or ≤1100° C., or ≤1050° C., or ≤1000° C., or ≤950° C., or ≤900° C., or ≤850° C., or ≤800° C., or ≤700° C., or ≤650° C., or ≤600° C., or ≤550° C. This also depends on the softening temperature of the substrate, which should not be exceeded.

According to at least one embodiment, the glass matrix contains zinc oxide and belongs to the system zinc oxide, boron oxide and silicon dioxide (ZnO—B2O3-SiO2), bismuth oxide, boron oxide, zinc oxide and silicon dioxide (Bi2O3-B2O3-ZnO—SiO2) and/or zinc oxide and tellurium dioxide (ZnO—TeO2). The refractive index of zinc oxide-boron oxide-silicon dioxide is approximately 1.6. The refractive index for bismuth oxide, boron oxide, zinc oxide and silicon dioxide as a glass matrix is approximately 2.0, the glass matrix with tellurium dioxide with zinc oxide is also highly refractive and is approximately 1.9. Preferably, the conversion element is very stable to moisture.

In order to use such optoelectronic components for the automotive industry, it is advantageous if these components have a high moisture stability, for example, a stability at 1000 hours at 85° C. with 85% relative humidity. Tellurite glasses or silicate glasses or borate glasses containing silicon dioxide are preferably used as glass matrix. The silicon content of borate glasses is preferably ≥1 mol % and ≤20 mol %, preferably ≥3 mol %, preferably ≥5 mol %. Silicate glasses with a silicon dioxide content of ≥20 mol %, or ≥25 mol %, or ≥30 mol %, or 24 35 mol %, or ≥40 mol %, or ≥45 mol %, or ≥50 mol %, or ≥55 mol %, or ≥60 mol %, or ≥65 mol %, or ≥70 mol %, or ≥75 mol %, or ≥80 mol % can also be used. Preferably, the glasses contain zinc oxide with a proportion of at least 1 mol %, i.e., the component is not introduced via raw material impurities, but specifically, and a maximum of 50 mol %. Aluminosilicate glasses, for example, an alkaline earth aluminosilicate glass, can also be used.

According to at least one embodiment, the laser source has at least one laser beam with a dominant wavelength of 410-490 nm, preferably 430-470 nm, preferably 440-460 nm. Alternatively, more than one laser beam, e.g., six laser beams, can form the laser source, which is guided in parallel over the conversion element as a stack. One or more lasers with the same or different wavelengths can be used as the laser source.

According to at least one embodiment, the laser source is designed to emit radiation with a dominant wavelength from the UV, blue, green, yellow, orange, red and/or near IR spectral range. In particular, the laser beam has a wavelength from the blue spectral range.

According to at least one simple embodiment, the radiation of the laser source hits the conversion element directly during operation. In other words, no further layers, elements, lenses or optical elements are arranged between the laser source and the conversion element. Usually, however, especially when using several laser diodes, a primary optical system is used to pre-collimate the laser light, possibly combine it in a beam combiner and shape the beam path. Depending on the application and installation space, this primary optic can contain all common elements, e.g., lenses and lens stacks or arrays, or reflective optical elements. The use of refractive optical elements is also possible. The use of dichroic mirrors is also possible.

Alternatively, other elements or layers, such as reflection elements, can be arranged between the radiation of the laser source and the conversion element. In other words, during operation, the radiation from the laser source hits the conversion element indirectly via a reflection element or another optical element. For example, the reflection element can be a dichroic mirror. The dichroic mirror can be formed from several layers and, for example, have an alternating sequence of titanium dioxide and silicon dioxide layers. The dichroic mirror can be optimized for the glass matrix used. An optical element, for example, can be a lens.

Reflective LARP is a system in which, unlike transmissive LARP, the laser does not exit opposite the entry side of the conversion medium, but is reflected and exits again at the original entry side.

According to at least one embodiment, the radiation of the laser source is arranged dynamically or statically to the conversion element.

According to at least one embodiment, the radiation of the laser source hits the conversion element via a transmissive substrate during operation.

Embodiments also provide a method for manufacturing an optoelectronic component. Preferably, the method described here is used to manufacture the component described here. All definitions and embodiments of the component also apply to the method for manufacturing a conversion element and vice versa.

In at least one embodiment, the method of manufacturing a conversion element comprises the steps of:

A) providing a self-supporting conversion element at least into the beam path of a laser beam which is fabricated as follows prior to said providing:

B1) mixing of at least one conversion material and a glass powder and, where appropriate, other substances such as solvents and binders to produce a paste,

B2) applying the paste directly onto a substrate to form a first layer,

B3) drying the first layer at at least 75° C.,

B4) heating the substrate and the first layer to a temperature in particular at least as high as the temperature at which the glass matrix material of the first layer has a viscosity of 10⁵ dPa*s (floating point), the temperature being greater than 350° C., and optionally

B5) smoothing or roughening a surface of the first layer facing away from the substrate.

According to at least one embodiment, step B2) is carried out by doctoring, screen printing, stencil printing, dispensing or spray coating.

The conversion element described here can produce a smaller emitting light spot and thus a better contrast between the surfaces to be illuminated and those not to be illuminated. This can be observed, for example, by reduced scattered radiation or a reduced halo or corona environment around the illuminated surface compared to ceramic converters, for example.

These advantages can be applied especially in so-called scanning LARP systems for the automotive industry. In addition, the conversion elements described here may have a higher luminance compared to ceramic converters. With other conversion elements the spot widening is often so bad that the light area on the conversion element must be defined by an additional aperture in order to avoid or reduce an unintended halo or corona effect. With embodiments of the invention presented here, it may be possible to dispense with such an aperture due to the small spot widening, thus reducing costs.

In addition, the efficiency can be increased, especially for components with a high energy density and/or temperatures due to better heat dissipation. This reduces the temperature in the conversion materials and thus the thermal quenching of the conversion materials compared to organic matrix materials, which usually have a significantly poorer thermal conductivity of <0.5 W(m*K). The maximum operating performance and/or temperature can be increased before the so-called “thermal rollover” of the conversion material is generated or irreversible damage to the conversion element is caused.

The thermal rollover can take place as follows:

1. Heat is generated in the conversion element during operation (due to Stokes heat when converting from, e.g., blue to yellow; due to losses due to quantum efficiency <100% or due to absorption),

2. At higher temperatures, most conversion materials have thermal quenching, i.e., the quantum efficiency decreases with increasing temperature,

3. Thermal quenching generates more heat, which can lead to even more thermal quenching,

4. Thermal rollover occurs when, despite an increase in laser power (excitation), the total radiation or converted radiation does not continue to rise but may even fall.

According to at least one embodiment, there is no adhesive layer between the substrate and the glass matrix and/or the conversion material. In other words, the glass matrix with conversion material can be applied directly to or onto the substrate, for example, directly onto the coating of the substrate. In comparison, ceramic converters have to be bonded, whereby the adhesive usually has a low thermal conductivity and maximum thermal load capacity.

The production of the conversion element and/or component described here is cheaper compared to ceramic converters that have to be bonded to a substrate, as this process step is not required here. In addition, several conversion elements can be processed in a compound, for example, at wafer level by spray coating or doctoring, which are only separated afterwards. This simplifies the process and is more cost-effective than gluing on individual ceramic converters. In addition, different conversion materials (e.g., garnets with different doping or different Al/Ga or Lu/Y content) or a mixture of conversion materials can be used for the conversion element described here. The conversion elements described here therefore have greater flexibility than ceramic converters with regard to setting the color coordinates or the color rendering index (CRI) of the total radiation.

According to at least one embodiment, the conversion element is used in the automotive sector, for example, in headlamps. Alternatively, the conversion element can be used for projection applications, endoscopy or stage lighting.

The conversion element can be generated as a composite on a sapphire wafer. Once the sapphire wafer has been coated, it can be separated, for example, by sawing or laser cutting. Such a process can improve homogeneity or yield and reduce process costs.

According to at least one embodiment, more than one conversion material is embedded in the glass matrix. This allows the color location or the color rendering index (CRI) to be adjusted. For example, warm white mixed light can be produced by combining green and orange or red conversion materials. Changing the color location can change the visibility of a headlight or in a vehicle, for example, in rain, snow or fog.

According to at least one embodiment, the conversion material has an average particle diameter between 1 and 25 μm, in particular between 2 and 15 μm, preferably between 3 and 9 μm.

According to at least one embodiment, the conversion element is activated with an activator or dopant. The concentration of the dopant can be between 0.1% and 10%, for example, 3%, as with Y_{0.97}Ce_{0.03})₃Al₅O₁₂. Lanthanides or rare earths, for example, can be used as dopants.

According to at least one embodiment, the conversion element has no holes. This refers to inhomogeneities in the conversion element, such as pores or other holes designed to transmit blue light without conversion or scattering. This can be influenced, for example, by the particle size and particle shape of the conversion materials or by the addition of fillers or scattering particles or by filling the pores or holes with additional (preferably inorganic) material. This is particularly important if a collimated laser light is to be scattered or converted by the conversion element.

### BRIEF DESCRIPTION OF THE DRAWINGS

Further advantages, advantageous embodiment and further developments result from the following exemplary embodiments described in connection with the figures.

It is shown in:

FIGS. 1A to 2F show optoelectronic components according to an embodiment;

FIG. 3 shows an electron microscope image of a conversion element according to an embodiment;

FIG. 4A shows the produced conversion element of exemplary embodiment 2 in plan view according to an embodiment; and

FIG. 4B shows the color location homogeneity of exemplary embodiment 2 over the coated surface.

In the exemplary embodiment and figures, identical, similar or similarly acting elements can each be provided with the same reference signs. The elements shown and their proportions are not to be regarded as true to scale. Rather, individual elements such as layers, devices, components and regions can be displayed too large for better visualization and/or better understanding.

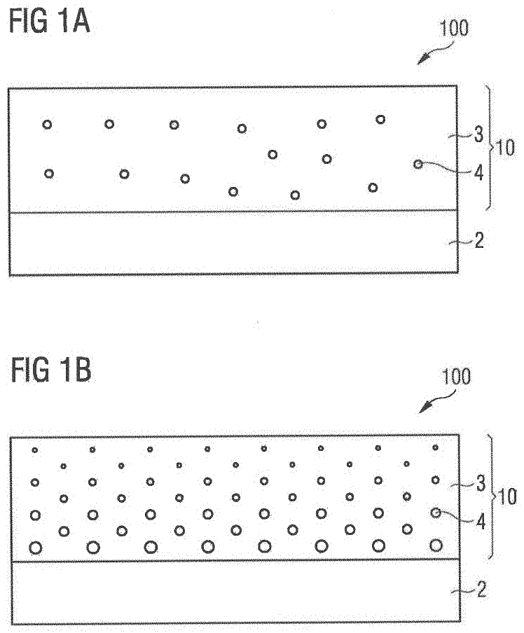

For example, FIGS. 1A and 1B show the substrate 2, which is illustrated thinner than the layer thickness of the first layer 10, although the layer thickness of substrate 2 (approx. 500 μm) is preferably greater than the layer thickness of the first layer 10 (maximum 200 μm).

### DETAILED DESCRIPTION OF ILLUSTRATIVE EMBODIMENTS

FIG. 1A shows a schematic cross-sectional representation of a conversion element 100 according to an embodiment. The conversion element 100 has a substrate 2 on which a glass matrix 3 is arranged. The conversion material 4, which is configured for wavelength conversion, is introduced into the glass matrix 3. The conversion material 4 and the glass matrix 3 form the first layer 10. In this example, the conversion material 4 is homogeneously distributed in the glass matrix 3.

FIG. 1B shows the distribution of the conversion material 4 in the glass matrix 3 by means of a concentration gradient or grain size gradient. Larger particles of the conversion material 4 are arranged towards substrate 2, smaller particles towards the opposite side of substrate 1. The glass matrix 3, for example, can be a tellurite glass. A garnet such as YAG:Ce can be used as conversion material 4.

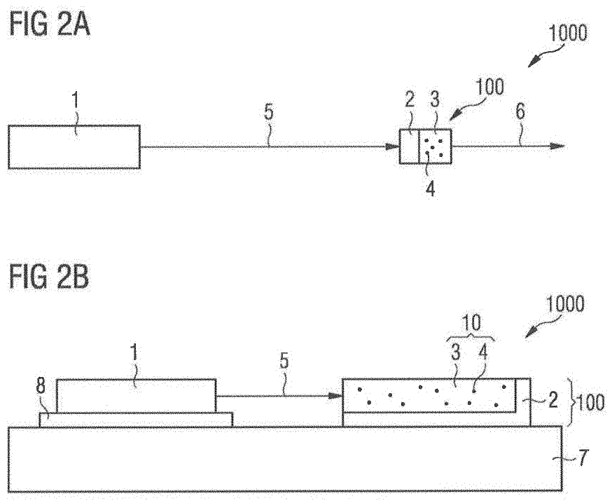

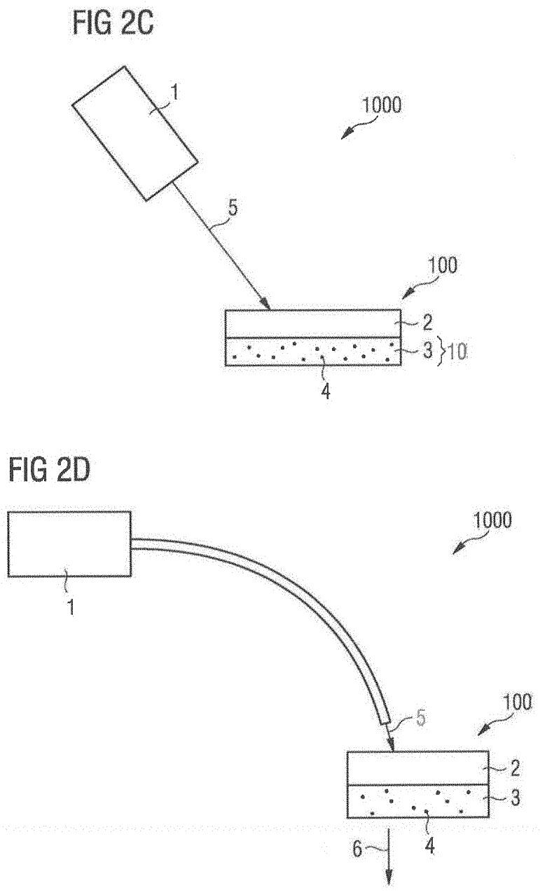

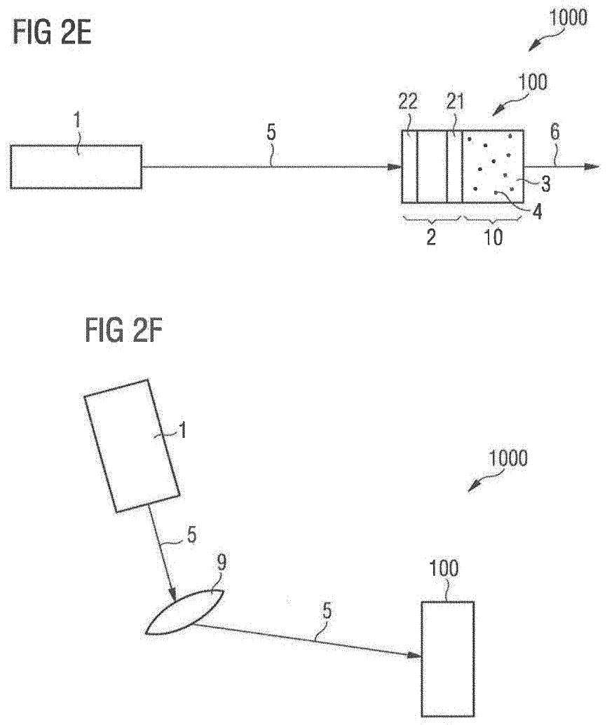

FIGS. 2A to 2F each show a side view of an optoelectronic component 1000, each with a conversion element 100 according to an embodiment, each arranged as a LARP arrangement. The distance between the laser source and conversion element may be several cm.

FIG. 2A shows a laser source 1 which is configured to emit a primary radiation (also called first radiation, laser beam or laser radiation) 5. The first radiation 5 strikes directly onto substrate 2, which is, for example, sapphire and which is transmissively shaped. The glass matrix 3 and the conversion material 4 are arranged downstream of the substrate 2. The conversion material 4 at least partially absorbs the primary radiation 5 and emits a secondary radiation 6. The conversion element 100 can be designed for full conversion or partial conversion. Preferably the conversion element 100 is adhesive-free here or in the other exemplary embodiments.

The conversion element 100 as shown in FIG. 2B shows a substrate 2 that is reflective. The substrate 2 extends over the base side of the first layer 10 with glass matrix 3, in which the conversion material 4 is embedded, and to a side surface of the first layer 10. The primary radiation 5 emitted by the laser source 1 thus impinges directly on the glass matrix 3, is converted by the conversion material 4 at least partially into radiation with changed wavelength and is reflected at the substrate 2. The laser source 1 can be arranged on a heat sink 8. The laser source 1 as well as the glass matrix 3 and the substrate 2 can also be arranged on a carrier 7. The carrier 7 can, for example, be a printed circuit board. Here, the laser beam 5 can irradiate vertically and/or at a certain angle to the conversion element 100.

In the embodiments of FIGS. 2A and 2B, the conversion element 100 can also be mounted mechanically immovable in relation to the laser source 1. The laser beam 5 of laser source 1 may be capable of scanning or moving (dynamically) on the surface of conversion element 100. This does not exclude the possibility that when the laser beam 5 moves, the laser source 1 is mounted mechanically immovable with respect to the conversion element 100.

Alternatively, the laser beam 5 can be arranged statically to the conversion element 100. The laser beam 5 of the laser source 1 is thus arranged on a fixed position of the surface of the conversion element 100.

FIG. 2C shows the arrangement of the laser source 1 at an angle to the substrate 2 and the glass matrix 3. The same applies to the conversion element 100 according to FIG. 2D. With the conversion element 100 of FIG. 2D, the laser source 1 is integrated into a light guide. The first layer 10, the glass matrix 3, the conversion material 4 and the substrate 2 can be designed in the same way as the previous embodiments. In FIG. 2C the laser source 1 and the substrate 2 with the glass matrix 3 are not arranged on a common carrier 7. As shown in FIG. 2C or FIG. 2D, the primary radiation 5 can reach the substrate 2 or the glass matrix 3 via a light guide in a freely moving manner. In both cases the substrate 2 is transmissive. For a reflective application the substrate 2 is formed reflective and arranged under the glass matrix 3. This means that the primary radiation 5 first hits the glass matrix 3 and then the reflective substrate 2 (not shown).

Between laser source 1 and the conversion element 100, optical elements 9, such as lens or collimator or mirror, can be arranged (see FIG. 2F).

FIG. 2E essentially corresponds to the embodiment of FIG. 2A. Unlike FIG. 2A, the embodiment of FIG. 2E has a dichroic coating 21 and/or an anti-reflective coating 22 as part of substrate 2. The dichroic coating 21 is arranged directly on the first layer 10. The anti-reflection coating 22 is arranged on the side of substrate 2 facing away from the first layer 10.

Exemplary embodiment 1: ZnO—B₂O₃-SiO2 as glass matrix 221 (refractive index about 1.6).

A paste produced with a powder of a glass consisting of zinc oxide, boron oxide, silicon dioxide and aluminum oxide, garnet as a conversion material powder and a conventional screen printing medium consisting of a binder and a solvent is applied to the substrate by one of the usual coating methods. Application can, for example, be carried out by means of doctoring with a layer thickness in the wet state between 30 and 200 μm, preferably 50 to 150 μm, in particular between 60 and 130 μm. After drying, the conversion element can be tempered at a temperature of, for example, 600° C. After tempering, the first layer 10 of the conversion element 100 may contain a conversion material 4 with a proportion of 25 vol %.

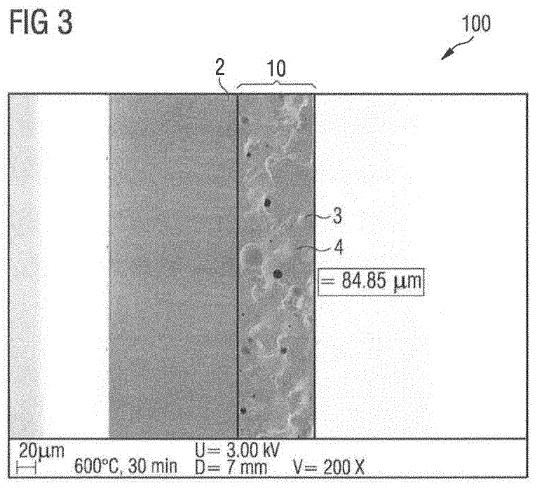

FIG. 3 shows an example of an electron microscope image (SEM) of a conversion element 100 according to an embodiment. The layer thickness of the first layer 10 is about 85 μm after a tempering temperature of about 600° C. for thirty minutes. The conversion material 4 has a proportion of approximately 22 vol % in the first layer 10. A borosilicate glass with good chemical resistance was used as substrate 2.

The measured quantum efficiency of the example of FIG. 3 is about 98% (absolute value). The measured absorption was 1.8% in a wavelength range from 680 to 720 nm. Both values show that the conversion elements 100 described here have excellent properties in the optoelectronic components 1000 described here. Quantum efficiency and absorption were measured with a Hamamatsu-Quantaurus arrangement.

Exemplary embodiment 2: ZnO—B₂O₃-SiO₂ as glass matrix (refractive index about 1.6).

A paste was produced from a glass powder consisting of zinc oxide, boron oxide, silicon dioxide and aluminum oxide, YAGaG as a conversion material in powder form and a conventional screen printing medium and then applied to a sapphire substrate with a dichroic coating. The application was done by doctoring. The gap height of the doctor blade was 60 μm. The thickness of the substrate was about 500 μm. After drying at 80°, the conversion element was tempered at 600° C. for one minute at a heating rate of 10 K/min. After the tempering step, the first layer 10 of the conversion element 100 contained a conversion material proportion of 28 vol % (calculated without pores) and a layer thickness of approximately 20 μm of the first layer 10.

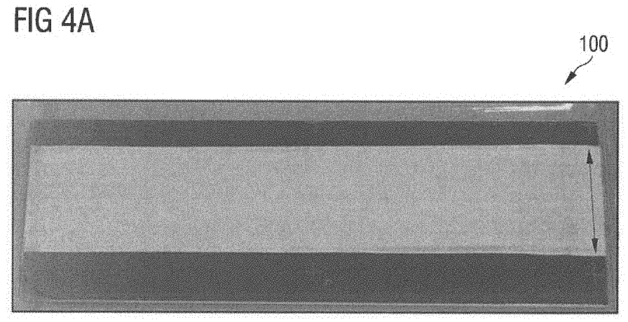

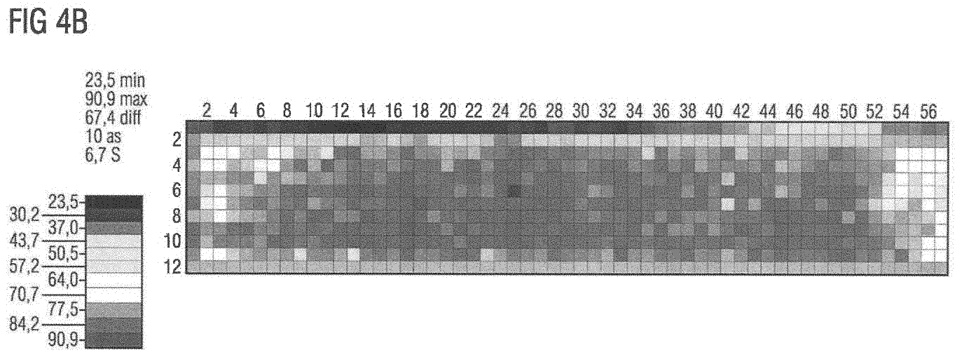

FIG. 4A shows the manufactured conversion element 100 of exemplary embodiment 2 in plan view. The width of the coating, here marked with an arrow, is approximately 1 cm.

FIG. 4B shows the color location distribution of the exemplary embodiment 2 over the coated area (as—number of steps; S—step size).

A small proportion of the aluminum oxide is contained in the glass powder of exemplary embodiments 1 and 2 in particular. Therefore, this was not taken into account in the formula of exemplary embodiments 1 and 2.

Exemplary embodiment 3: ZnO—B₂O₃-SiO₂ as glass matrix (refractive index about 1.6).

Exemplary embodiment 3 was manufactured like exemplary embodiment 2 and tempered at a temperature of 600° C. for thirty minutes. The thickness of the tempered first layer is approximately 20 μm.

Exemplary embodiment 4: ZnO—B₂O₃-SiO₂ as glass matrix (refractive index approx. 1.6).

Exemplary embodiment 4 was manufactured like exemplary embodiment 3, but with a gap height of 60 μm. The thickness of the tempered first layer is approximately 13 μm.

The exemplary embodiments described in connection with the figures and their features can also be combined with each other according to further exemplary embodiments, even if such combinations are not explicitly shown in the figures. Furthermore, the exemplary embodiments described in connection with the figures may have additional or alternative features as described in the general part.

The invention is not limited by the description in connection with the exemplary embodiments to these. Rather, the invention includes any new feature as well as any combination of features, which in particular includes any combination of features in the patent claims, even if that feature or combination itself is not explicitly mentioned in the patent claims or exemplary embodiments.

1-18. (canceled)

19. An optoelectronic component comprising:
at least one laser source configured to emit at least one laser beam with primary radiation; and
a self-supporting conversion element arranged in a beam path of the laser beam,
wherein the self-supporting conversion element comprises a substrate followed by a first layer, the first layer being directly bonded to the substrate and comprising at least one conversion material embedded in a glass matrix,
wherein the glass matrix has a proportion of 50 vol % to 80 vol % inclusive in the first layer,
wherein the substrate is free of the glass matrix and of the conversion material and mechanically stabilize the first layer, and
wherein the first layer has a layer thickness of less than 200 μm.

20. The optoelectronic component according to claim 19, wherein the laser beam is dynamically arranged with respect to the conversion element.

21. The optoelectronic component according to claim 19, wherein the laser beam is statically arranged with respect to the conversion element.

22. The optoelectronic component according to claim 19, further comprising a dichroic layer stack disposed between substrate and the glass matrix,
wherein the dichroic layer stack is transmissive for the primary radiation,
wherein the conversion material is configured to at least partially convert the primary radiation into secondary radiation with a longer wavelength, and
wherein the dichroic layer stack is configured to at least partially reflected the secondary radiation.

23. The optoelectronic component according to claim 19,
wherein the laser beam strikes the conversion material and at least partially converts the primary radiation of the laser beam into secondary radiation with a longer wavelength,
wherein the primary and secondary radiation are reflected on the substrate or on the substrate with a reflective layer and/or a dichroic layer stack located between the substrate and the glass matrix, and
wherein the reflected radiation emerges again via the conversion material.

24. The optoelectronic component according to claim 19, wherein the substrate is glass, ceramic, glass-ceramic, metal or sapphire.

25. The optoelectronic component according to claim 19, wherein the substrate has a higher softening temperature than the glass matrix.

26. The optoelectronic component according to claim 19, wherein the substrate is arranged between the laser source and the first layer in a transmissive arrangement, or wherein the first layer is arranged between the laser source and the substrate in a reflective arrangement.

27. The optoelectronic component according to claim 19, wherein the first layer has a surface facing away from the substrate which is structured.

28. The optoelectronic component according to claim 19, wherein the glass matrix is oxidic and comprises lead oxide, bismuth oxide, boron oxide, silicon dioxide, tellurium oxide, phosphorus pentoxide, aluminum oxide or zinc oxide.

29. The optoelectronic component according to claim 19, wherein the glass matrix comprises ZnO, B₂O₃ and SiO₂.

30. The optoelectronic component according to claim 19, wherein the glass matrix comprises ZnO, at least one glass former and a network converter or an intermediate oxide comprising at least one of the following materials: alkaline earth oxide, alkali oxide, aluminum oxide, zirconium oxide, niobium oxide, tantalum oxide, tellurium oxide, tungsten oxide, molybdenum oxide, antimony oxide, silver oxide, tin oxide, or rare earth oxide.

31. The optoelectronic component according to claim 19, wherein the glass matrix is a tellurite glass, a silicate glass, an aluminosilicate glass, a borate glass, a borosilicate glass or a phosphate glass.

32. The optoelectronic component according to claim 19, wherein the glass matrix has a content of at most 75 vol % in the first layer.

33. The optoelectronic component according to claim 19, wherein the at least one conversion material is selected from the group consisting of (Y,Gd,Tb,Lu)₃(Al,Ga)₅O₁₂:Ce³⁺, (Sr,Ca)AlSiN₃:Eu²⁺, (Sr,Ba,Ca,Mg)₂Si₅N₈:Eu²⁺, (Ca,Sr,Ba)₂SiO₄:Eu²⁺, α-SiAlON:Eu²+, β-SiAlON:Eu²⁺, (Sr,Ca)S:Eu², (Sr,Ba,Ca)₂(Si,Al)₅(N,O)₈:Eu²⁺, (Ca,Sr)₈Mg(SiO₄)₄Cl₂:Eu²⁺, and (Sr,Ba)Si₂N₂O₂:Eu²⁺.

34. The optoelectronic component according to claim 19, wherein at least two different conversion materials are embedded in the glass matrix.

35. A method for manufacturing an optoelectronic component according to claim 19 the method comprising:
providing the self-supporting conversion element at least into the beam path of the laser beam, wherein the self-supporting conversion element is manufactured by:
mixing of at least one conversion material and a glass powder which, after a subsequent glazing step, produces the glass matrix, and optionally further substances for producing a paste;
applying the paste directly onto the substrate to form the first layer;
drying the first layer at not less than 75° C.;
heating the substrate and the first layer to a temperature at least as high as a temperature at which the glass matrix material of the first layer has a viscosity of 10⁵ dP a*s, the temperature being greater than 350° C.; and
optionally smoothing or roughening a surface of the first layer facing away from the substrate.

36. The method according to claim 35, wherein applying the paste comprises doctoring, screen printing, stencil printing, dispensing or spray coating.
